(19) United States
(12) Patent Application Publication
(10) Pub. No.: US 2006/0125114 A1
(43) Pub. Date: Jun. 15, 2006

(54) Electrical connection through nonmetal

(75) Inventor: David A. Ruben, Mesa, AZ (US)

Correspondence Address: MEDTRONIC, INC., 710 MEDTRONIC PARK, MINNEAPOLIS, MN, 55432-9924, US

(73) Assignee: Medtronic, Inc.

(21) Appl. No.: 11/350,624

(22) Filed: Feb. 9, 2006

Related U.S. Application Data
(62) Division of application No. 10/253,555, filed on Sep. 24, 2002, now abandoned.

(51) Int. Cl. H01L 23/48; H01L 21/48

(52) U.S. Cl. 257/778; 438/613; 257/737; 438/108; 257/686; 257/E23.067

(57) ABSTRACT

A low resistance path extends from a first region of a semiconductor substrate to a second region thereof. The low resistance path is produced by depositing a metal such as aluminum on the surface of the substrate and then directing a laser beam onto the metal causing the metal and a portion of the substrate beneath the metal to melt forming an alloy of the metal and the substrate material.

### TECHNICAL FIELD

This invention relates generally to electrical connections or contacts through a nonmetal and to a method for making same. More particularly, the invention relates to an alloyed electrical connection through a nonmetal (e.g. semiconductor, insulator, etc.) and to a method for making same. Still more particularly, the invention relates to a method for making an electrical connection from one side of a semiconductor wafer or die to the other side by means of laser alloying or mixing a metal with a semiconductor material and to the resulting structure.

### BACKGROUND OF THE INVENTION

Many high power/voltage devices and certain other types of devices are configured with contacts or electrodes on the backside of the device or wafer (i.e. the side opposite the side into/on which active devices are formed). Typically, connection is made to the backside of such devices during packaging or assembling. The backside electrode can be used for grounding or electrically biasing the integrated circuits on the die. The backside electrode can be formed as a thin metal film that covers the entire backside (or portion thereof) of the die or device. The semiconductor substrate of a die can also act as an electrode with respect to the integrated circuits on the device.

There are several known methods for contacting a backside electrode (or semiconductor substrate) of a type described above. For example, a device may be mounted to a package or a substrate using a conductive adhesive, solder, or a silicon/metal eutectic. Front-side connection may be accomplished by wire-bonding or other well-known techniques. Another known method involves the diffusion or implantation of dopants through the front and/or backside of the device to make the desired connection. Still another known method involves the creation of vias (holes) through the silicon substrate using, for example, laser drilling, etching, or other well-known techniques and then metallizing the walls of the vias. The vias may then be filled with, for example, polysilicon or a polymer.

Unfortunately, each of the above known techniques presents certain problems. The use of conductive adhesives, soldering, or backside eutectic bonds all require access to the backside electrode, which in many cases dictates that a larger package be employed. In certain applications, such in the case of implantable devices, factors which cause package size to increase should be avoided. Dopant diffusion or implantation is a time consuming process which becomes more complex with increasing device thicknesses. Contacts having non-uniform conductivity may be produced, and the long diffusion cycles may result in lateral dopant diffusion which may impact the doped regions of other active devices. The creation of holes or trenches may weaken device structure. If an etching technique (e.g. reactive ion etching) is employed to produce the holes or trenches, surface silicon dioxide (SiO₂) is produced requiring additional thermal processes in order to achieve suitable omic contacts.

It should therefore be appreciated that it would be desirable to provide a method for producing an electrical contact from a first surface (e.g. a front surface) of a device (e.g. a semiconductor device) to a second surface (e.g. the backside surface), substrate, or other region of the device. The resulting low-resistance electrical connection or coupling through the device enables the device to be mounted on a substrate or package without the need for a backside connection thus facilitating the use of flip-chip bonding, tape automated bonding (TAB) or any other single-side mechanism. This approach also permits the direct stacking of planar devices without the need for flex-tape or other interposers.

### SUMMARY OF THE INVENTION

According to an aspect of the invention, there is provided a method for producing a low resistance path through a nonmetal. The metal is first deposited on a surface of the nonmetallic material. A laser beam is then applied to the metal to alloy the metal and the nonmetallic material therebeneath to create the low resistance path.

According to a further aspect of the invention there is provided a method for producing a conductive path from a front surface of a semiconductor material to a region beneath the front surface. The metal is deposited on at least a portion of the front surface. A laser beam is then applied to the metal portion to alloy the metal and the semiconductor material in a region which extends from the front surface toward the region beneath the front surface.

According to a still further aspect of the invention there is provided a semiconductor device which comprises a semiconductor substrate having first and second regions. A low resistance path extends from the first region to the second region and is comprised of an alloy of a metal and nonmetal.

### BRIEF DESCRIPTION OF THE DRAWINGS

The following drawings are illustrative of particular embodiments and therefore do not limit the scope of the invention, but are presented to assist in providing a proper understanding. The drawings are not to scale (unless so stated) and are intended for use in conjunction with the explanations in the following detailed description. The present invention will hereinafter be described in conjunction with the appended drawings, wherein like reference numerals denote like elements, and:

FIG. 1 is a cross-sectional view of nonmetallic substrate having a conductive path formed therein utilizing the inventive process;

FIG. 2 is a cross-sectional view illustrating how the inventive process can be utilized to produce a conductive path from a first surface of a substrate to a second surface thereof;

FIG. 3 is a cross-sectional view illustrating how conductive paths may be produced from opposite sides of a substrate in accordance with the teachings of the present invention;

FIG. 4 is a cross-sectional view illustrating how the inventive process can be utilized to produce a conductive path from the surface of a substrate to a doped region in the substrate;

FIGS. 5-8 illustrate an alternative process for producing a conductive path through a nonmetallic substrate;

FIG. 9 is a cross-sectional view illustrating how the inventive process can be utilized to produce a conductive path from a first doped region to a second doped region;

FIG. 10 illustrates the process of FIG. 9 wherein laser energy is applied to both sides of a substrate;

FIGS. 11-14 are plan views illustrating several arrangements of contacts produced in accordance with the present invention;

FIG. 15 is a cross-sectional view of a stacked semiconductor device incorporating the teachings of the present invention; and

FIG. 16 is a cross-sectional view of a two-sided device incorporating the teachings of the present invention.

### DESCRIPTION OF THE PREFFERED EXEMPLARY EMBODIMENTS

The following description is exemplary in nature and is not intended to limit the scope, applicability, or configuration of the invention in any way. Rather, the following description provides a convenient illustration for implementing an exemplary embodiment of the invention. Various changes to the embodiment may be made in the function and arrangement of the elements as described herein without the departing from the scope of the invention.

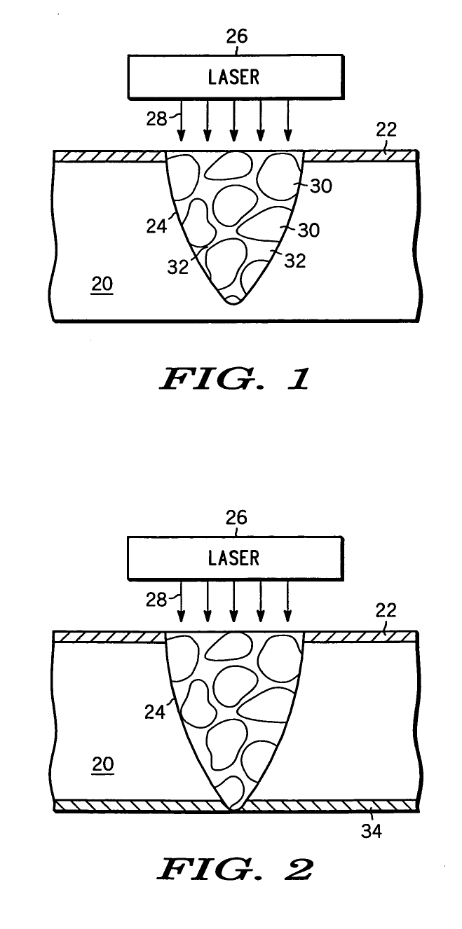

Generally speaking, the invention relates to the production of a low resistance path from the front side of a nonmetallic substrate to the backside or other region of the substrate. The low resistance path is produced by mixing or alloying a metal such as aluminum, chromium, titanium, etc., with the nonmetallic substrate. The nonmetallic substrate may comprise an insulator such as glass or a semiconductor material such as silicon, gallium arsenide, gallium phosphide, etc. The invention will be described in connection with the production of a low resistance path or electrical contact through silicon produced by laser treating a layer of aluminum deposited on the surface of a silicon substrate. Aluminum on silicon has been chosen as a preferred embodiment because of the favorable conductivity and solubility characteristics of silicon in aluminum. As a result, aluminum reduces silicon dioxide (SiO₂) to silicon (Si) and forms a good ohmic contact with silicon. As stated previously, however, the invention is not limited to the use of aluminum on silicon, and other metallic and nonmetallic materials may be utilized. The preferred embodiments will now be described in connection with FIGS. 1-16.

Referring to FIG. 1, there is shown a nonmetallic substrate 20 having a metallic layer 22 (e.g. aluminum) disposed thereon. Metallic layer 22 may be deposited by any one of a number of known techniques. To produce a region 24 of high conductivity, a laser system 26 generates laser beam 28 which is directed at the surface metal 22 or portion thereof as shown. The intensity of the laser beam should be sufficient to melt and mix the aluminum and the silicon. For example, laser pulses may be generated having a peak power of 1500 watts and a duration of 0.4 milliseconds (i.e. 0.6 joule). The laser beam may have a diameter of, for example, from 20 to 200 microns and be generated by a Nd:YAG (neodymium yttrium aluminum garnet) laser (e.g. 1,064 nanometer wavelength) of the type available from Lasag located in Thun, Switzerland and bearing a model number SLS200C. It should be appreciated, however, that other types of lasers such as diode lasers, carbon dioxide lasers, and the like could be employed. Pulse shaping of the laser intensity with respect to time may also be utilized to control cooling rate. In this case, pulse duration may be 10-20 milliseconds.

Laser beam pulses as short as several hundred microseconds are sufficient to induce mixing of the silicon and aluminum which is then supported and driven by the Marangoni forces (convection) which result from variations in surface tension with temperature. These forces comprise both thermal and solutal forces, the thermal forces dominating with high temperature gradients. Marangoni convection may be described as the sum of the thermal forces and the solutal forces as defined by the equation:

$${}_{.}^{}{τ}{}_{.}^{} = μ ( \frac{\partial u}{\partial {y}^{\cdot }} ) {•}_{\cdot } ( \frac{\partial γ}{\partial {T}^{\cdot }} ) ( \frac{\partial T}{\partial {x}^{\cdot \cdot }} ) {\sum }_{i} ( \frac{\partial y}{\partial {ai}^{\cdot }} ) ( \frac{\partial ai}{\partial x} ) •$$

where
=shear stress due to surface tension gradients,
=viscosity,
u=velocity component parallel to the surface,
x, y are coordinates parallel and perpendicular to the surface,
=surface tension,
=local temperature, and
ai=thermodynamic activity of alloy element i

For a complete discussion of Marangoni convection, the interested reader is directed to Laser Welding by W. W. Duley, published by John Wiley and Sons, Inc., 1999.

As the resulting melt cools (e.g. for approximately 5 milliseconds), regions of pure silicon 30 (e.g. 98.8% pure silicon) freeze out first. Next, the eutectic phase 32 (e.g. 87.4% aluminum, 12.6% silicon) freezes out filling the gaps between regions 30 thus producing a three dimensional, substantially solid, conductive path or web extending into the wafer, die, or substrate 20 as is shown in FIG. 1. It should be understood that while the laser energy may be locally very high, the total energy absorbed by the device is sufficiently low so as not to affect adjacent structures.

FIG. 2 is a cross-sectional view illustrating how the inventive process can be utilized to provide a low resistance path between a top surface (aluminum layer 22) and a bottom surface (metallic layer 34). As was the case previously, metallic layer 34 may be comprised of any one of a number of suitable metals such as aluminum, chromium, titanium, etc., and may be deposited on the lower surface of the die by any one of a number of known techniques.

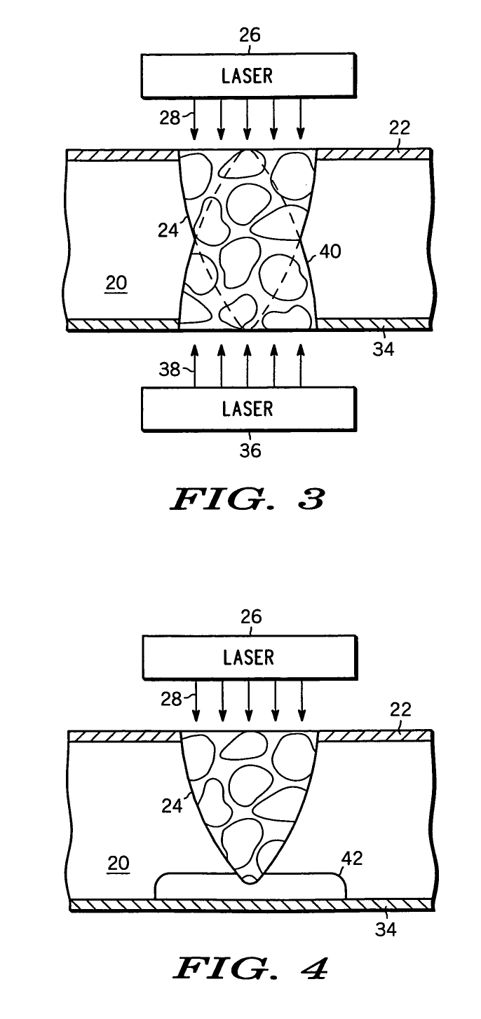

FIG. 3 is a cross-sectional diagram illustrating how a low resistance path can be produced through a nonmetallic substrate by utilizing the above-described laser alloying process from both sides of the substrate. As was the case in connection with FIG. 2, a laser 26 generates a laser beam 28 which is impinges upon a portion of aluminum layer 22 to create highly conductive region 24 comprised of an aluminum-silicon alloy. Additionally however, a second laser beam 38 (e.g. generated by a second laser generator 36) is directed at a portion of metallic layer 34 (e.g. aluminum) to produce a conductive region 40 which is similarly comprised of a silicon-aluminum alloy. As can be seen, regions 24 and 40 overlap to produce the desired low resistance path between the upper and lower surfaces of substrate 20. It should be understood that regions 24 and 40 could be made to grow through the entire thickness of substrate 20 as is shown in FIG. 3, or if desired, to only a controlled predetermined depth.

FIG. 4 is a cross-sectional view illustrating how a low resistance path produced in accordance with the above-described teachings can be utilized to produce a conductive path from a surface of a substrate to a diffused region within the substrate. As can be seen, substrate 20 has a metal layer 22 (e.g. silicon) on an upper surface thereof. Substrate 20 has a doped region 42 formed therein using any one of a number of known semiconductor techniques. A metal layer 34 (e.g. aluminum) it is deposited on the lower surface of substrate 20 and doped region 42. As laser beam 28 is directed onto a portion of aluminum layer 22, the aluminum and silicon beneath the laser beam mix to form a conductive alloy which extends into doped region 42.

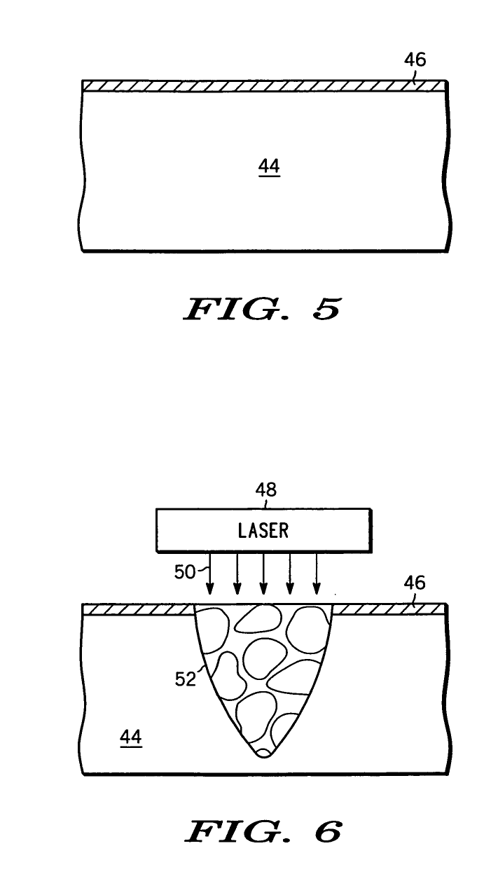

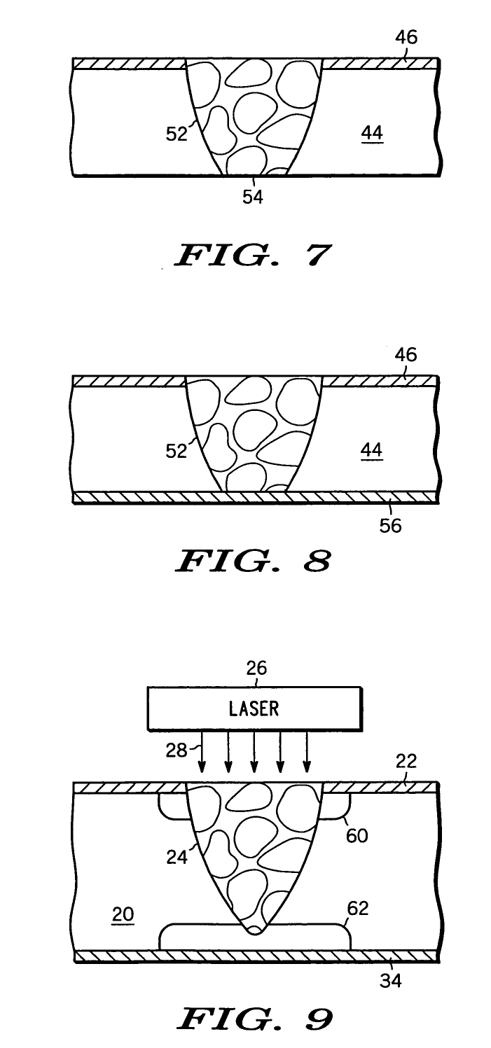

FIGS. 5-8 are cross-sectional views illustrating an alternative method of producing a low resistance path from a first surface of a substrate to provide a backside connection in accordance with the teachings of the present invention. Referring first to FIG. 5, there is shown a nonmetallic substrate 44 (e.g. silicon) having a metallic layer 46 (e.g. aluminum) disposed thereon using any one of a number of known techniques. As shown in FIG. 6, laser system 48 produces a laser beam 50 of the type described above which is directed onto a portion of metallic layer 44 to produce high conductivity alloy region 52 as was described in connection with FIG. 1. Next, as shown in FIG. 7, the rear or lower portion of substrate 44 is removed so as to expose a lower surface portion 54 of alloyed region 52. Finally, as shown in FIG. 8, in metallic layer 56 (e.g. aluminum, chromium, titanium, etc.) is deposited using known techniques on the lower surface of substrate 44, thus making electrical contact with conductive region 52.

FIG. 9 is a cross-sectional view illustrating how the inventive laser alloying process can be utilized to provide a high conductivity path between a first doped region 60 and a second doped region 62. As can be seen, doped region 60 is formed through an upper surface of substrate 20 and metal layer deposited thereon. A second doped region 62 is deposited into a lower portion of substrate 20. By applying laser energy in the manner above-described to a portion of aluminum layer 22, which is in electrical contact with doped region 60, a region of high conductivity is produced in region 60 and extends through substrate 20 into doped region 62.

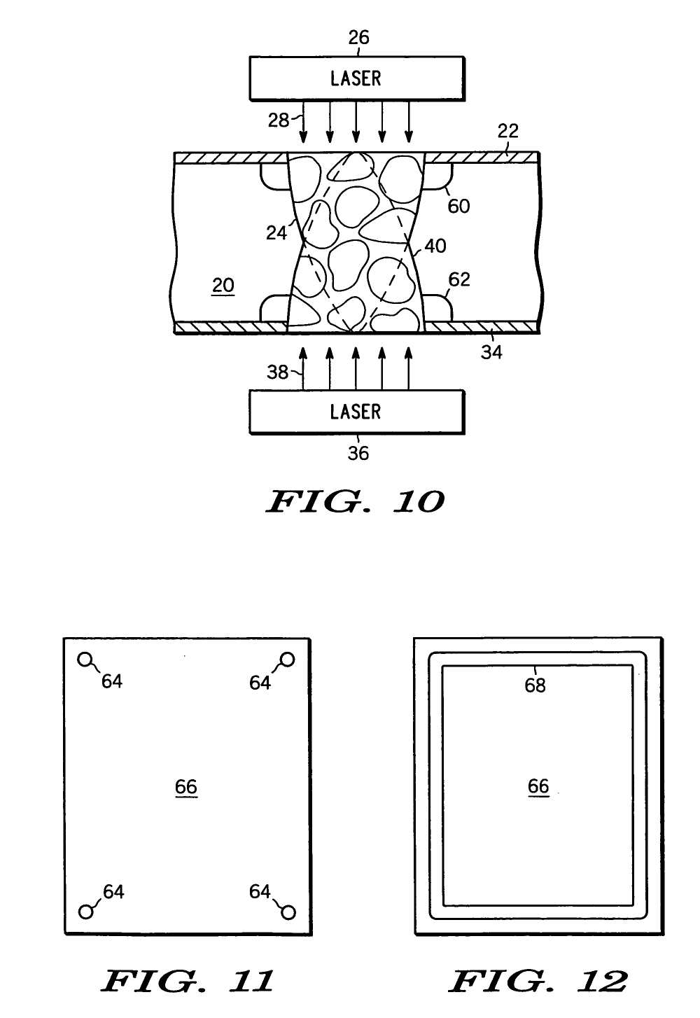

FIG. 10 is a cross-sectional view illustrating the connection of doped regions 60 and 62 which are adjacent to the upper and lower surfaces respectively of substrate 20 using the technique described above in connection with FIG. 3. That is, the laser mixing or alloying is accomplished through both the upper and lower metallic layers 22 and 34. As was the case previously, the mixing depth of high conductive regions 24 and 40 may extend through the entire thickness of the substrate or may, in fact, only extend to a controlled predetermined depth.

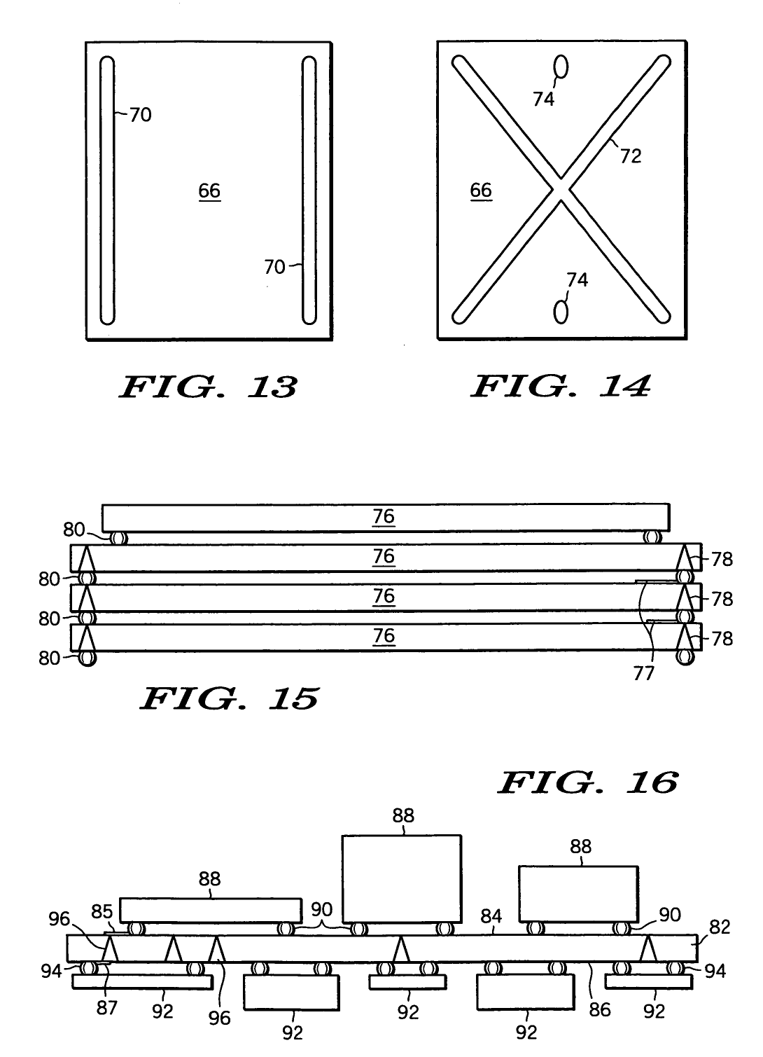

It should be apparent now that by directing a laser beam of sufficient intensity onto a metal-coated nonmetal, a melting and alloying process occurs between the metal and the nonmetal and extends into the body of the nonmetal to create a conductive path. These laser-alloyed regions may be individual and separate as is shown at regions 64 in substrate 66 of FIG. 11, which is a top view of semiconductor substrate 66. Alternatively, the laser-alloyed portion may form a single continuous pattern as is shown at 68 in FIG. 12. The pattern may contain a plurality of lines such as is shown at 70 in FIG. 13, or may be a combination of a common node 72 and separate nodes 74 as is shown in FIG. 14. It should be clear from FIGS. 11-14 that an endless variety of combinations of common nodes and/or separate nodes are possible.

FIG. 15 is a cross-sectional view illustrating how dies could be stacked using the laser formed through-connections in accordance with the teachings of the present invention and utilizing with bump contacts. For example, referring to FIG. 15, there is shown a plurality of silicon substrates 76 each presumably having a plurality of active devices formed therein and each having conductive patterns 77 on the surface thereof. Each substrate 76 is provided with one or more laser formed through connections 78 produced in the manner described hereinabove. Through-connections 78 are electrically coupled together by means of conductive bumps 80. In this manner, active devices on each of the substrates 76 may be placed in electrical connection with the electrical or active devices on other substrates through the various conductor patterns on the surface of each substrate. Furthermore, as is illustrated in FIG. 16, components mounted on one surface of a substrate may be electrically connected to devices on an opposite surface of the substrate through the use of laser formed through-connections of the type previously described. For example, referring to FIG. 16, there is shown a nonconductive substrate 82 having an upper surface 84 and a lower surface 86. Surface 84 has a conductive metallization pattern 85 deposited thereon in accordance with well-known techniques providing electrical coupling between components mounted on surface 84. Thus, for example, a plurality of components 88 such as integrated circuits, capacitors and the like may be electrically coupled to surface metallization pattern 85 by means of bump contacts 90. Similarly, a plurality of components 92 may be electrically coupled to a metallization pattern 87 on surface 86 by means of bump contacts 94. Predetermined portions of the metallization layer on surface 84 may then be coupled to other portions of the metallization pattern on layer 86 by means of laser formed through-connections 96 so as to produce a desired operational relationship between components 88 and components 92 on opposite sides of substrate 82.

Thus, there has been provided an improved method for providing a low resistance path through a nonmetal (e.g. such as an insulator or semiconductor substrate) which does not require access to both sides of the substrate thus facilitating the process for making backside connections. This permits the device to have a smaller package and results in fewer production steps. Unlike the case of diffused contacts, the resulting laser formed alloy connections have a substantially uniform distribution. The inventive process is applicable to high or low power/voltage devices including micromechanical systems such as accelerometers. Integrated circuits may be stacked using the inventive laser formed through-connections and flip-chip bumping. The need for creating, metallizing, and filling vias has been eliminated.

In the foregoing specification, the invention has been described with reference to specific embodiments. However, it should be appreciated that various modifications and changes can be made without departing from the scope of the invention as set forth in the appended claims. Accordingly, the specification and drawings should be regarded as illustrative rather than restrictive, and all such modifications are intended to be included within the scope of the present invention.

1. A method for producing a conductive path from a first region of a semiconductor material to a second region of said semiconductor material, comprising:
depositing a metal on at least a portion of said first region; and
directing a laser beam onto said metal to alloy said metal and said semiconductor material to produce a conductive path extending from said first region toward said second region, wherein said second region is a second surface.

2. A method according to claim 1 wherein said first surface is a front surface and said second surface is a backside surface.

3. A method according to claim 1 wherein said first region is a first doped region.

4. A method according to claim 1 wherein said second region is a second doped region.

5. A method according to claim 1 wherein said second region is a first doped region.

6. A method according to claim 1 wherein said semiconductor is gallium arsenide.

7. A method for providing a low resistance path from a first surface of a die of a semiconductor material to a second surface of the die, comprising:
depositing a metal on said first surface;
directing a laser beam onto said metal to create an alloy of said metal and said semiconductor material, said alloy forming said low resistance path extending from said first surface into said die;
removing a portion of said die to expose said low resistance path at said second surface; and
depositing a conductive material on at least a portion of said second surface to contact with said low resistance path.

8. A method according to claim 7 wherein said semiconductor material is silicon.

9. A method according to claim 8 wherein said metal is aluminum.

10. A method according to claim 9 wherein said conductive material is aluminum.

11. A semiconductor device, comprising:
a semiconductor substrate having first and second regions; and
a low resistance path extending from said first region toward said second region, said low resistance path comprised of an alloy of a metal and a nonmetal.

12. A semiconductor device according to claim 11 wherein said first region comprises a first surface of said device and said second region comprises a second opposite surface of said device.

13. A semiconductor device according to claim 11 wherein said first region further comprises a first doped region.

14. A semiconductor device according to claim 13 wherein said second region further comprises a second doped region.

15. A semiconductor device according to claim 12 wherein said metal is aluminum.

16. A semiconductor device according to claim 15 wherein said nonmetal is a semiconductor.

17. A semiconductor device according to claim 16 wherein said semiconductor is silicon.

18. An electronic device, comprising:
a substrate material having first and second opposite surfaces;
at least a first contact pattern comprised of a first metal on said first surface;
at least a second contact pattern comprised of a second metal on said second surface; and
at least one feed-through contact comprised of an alloy of said first metal and said substrate material for electrically coupling said first contact pattern and said second contact pattern.

19. An electronic device according to claim 18 wherein said first metal is aluminum.

20. An electronic device according to claim 19 wherein said substrate is a semiconductor.

21. An electronic device according to claim 20 wherein said semiconductor is silicon.

22. An electronic device according to claim 19 wherein said substrate is an insulator.

23. A stacked electronic device, comprising:
a first substrate having a first conductive pattern thereon;
a second substrate having a second conductive pattern thereon, said second substrate stacked on said first substrate;
a bump contact electrically coupled to said first conductive pattern; and
at least one feed through conductor comprised of an alloy of a metal and a nonmetal and extending into said second substrate for electrically coupling said bump contact to said second conductive pattern.

24. The attached electronic device of claim 23 wherein said stacked electronic device is adapted for use in an implantable medical device.
